(19) United States
(12) Patent Application Publication
(10) Pub. No.: US 2024/0079501 A1
(43) Pub. Date: Mar. 7, 2024

(54) THIN FILM TRANSISTOR AND MANUFACTURING METHOD THEREFOR, ARRAY SUBSTRATE, AND DISPLAY PANEL AND DEVICE

(71) Applicants: HEFEI BOE DISPLAY TECHNOLOGY CO., LTD., HEFEI, ANHUI (CN); BOE TECHNOLOGY GROUP CO., LTD., BEIJING (CN)

(72) Inventors: Qi LIU, BEIJING (CN); Jiantao LIU, BEIJING (CN); Jianbo XIAN, BEIJING (CN); Wei ZHANG, BEIJING (CN); Jincheng GAO, BEIJING (CN); Liangliang JIANG, BEIJING (CN)

(73) Assignees: HEFEI BOE DISPLAY TECHNOLOGY CO., LTD., HEFEI, ANHUI (CN); BOE TECHNOLOGY GROUP CO., LTD., BEIJING (CN)

(21) Appl. No.: 18/261,348

(22) PCT Filed: Oct. 22, 2021
(86) PCT No.: PCT/CN2021/125628

§ 371 Date: Jul. 13, 2023

(30) Foreign Application Priority Data
May 20, 2021 (CN) 202110551192.5

(51) Int. Cl. H01L 29/786; H01L 29/423; H01L 29/66

(52) U.S. Cl. CPC H01L 29/78696; H01L 29/42364; H01L 29/42384; H01L 29/6675; H01L 29/78663

(57) ABSTRACT

A thin film transistor and a manufacturing method therefor, an array substrate, and a display panel and device. The thin film transistor includes: a gate (11) and an active layer (12) that are located on one side of a base substrate (10); a gate insulation layer (13) located between the gate (11) and the active layer (12); and a source (14) and a drain (15) that are spaced apart and both are in contact with the active layer (12), wherein a first ratio of the thickness of the gate insulation layer (13) and the thickness of the active layer (12) ranges from 3 to 4.

### CROSS-REFERENCE TO RELATED APPLICATION

The present application is a U.S. National Stage Application under 35 U.S.C. § 371 of International Patent Application No. PCT/CN2021/125628, filed on Oct. 22, 2021, which is based on and claims priority to China Patent Application No. 202110551192.5 filed on May 20, 2021, the disclosures of both of which are incorporated by reference herein in their entireties.

### TECHNICAL FIELD

The present disclosure relates a thin film transistor and a manufacturing method therefor, an array substrate, and a display panel and device.

### BACKGROUND

With the development of the display technology, the resolution of the display panel is increasing, and the number of the pixels per unit area is increasing.

With the continuous popularization of 5G, the ultra-high-definition large size display panel will be widely applied in fields such as medical field, exhibition field and live events.

### SUMMARY

According to one aspect of the embodiments of the present disclosure, a thin film transistor is provided. The thin film transistor comprises: a gate and an active layer which are located on one side of a base substrate; a gate insulating layer located between the gate and the active layer; and a source and a drain spaced apart from each other, and both in contact with the active layer, wherein a first ratio of a thickness of the gate insulating layer to a thickness of the active layer ranges from 3 to 4.

In some embodiments, the active layer comprises: a first semiconductor layer which is heavily doped and comprises a first portion and a second portion spaced apart from each other, wherein the first portion is in contact with the source and the second portion is in contact with the drain; and a second semiconductor layer located between the first semiconductor layer and the gate insulating layer, and in contact with the gate insulating layer.

In some embodiments, a second ratio of the thickness of the gate insulating layer to a thickness of the first semiconductor layer ranges from 15 to 24.

In some embodiments, the second ratio ranges from 18 to 22.

In some embodiments, the first portion of the first semiconductor layer is in contact with a third portion of the second semiconductor layer, and the second portion of the first semiconductor layer is in contact with a fourth portion of the second semiconductor layer, wherein a portion of the second semiconductor layer between the third portion and the fourth portion is a channel, a width-length ratio of the channel ranging from 0.52 to 0.6.

In some embodiments, the width-length ratio of the channel ranges from 0.54 to 0.58.

In some embodiments, the source is in contact with a fifth portion of the second semiconductor layer, the drain is in contact with a sixth portion of the second semiconductor layer, a thickness of each of the source and the drain is a first thickness, and a thickness of each of the fifth portion and the sixth portion is a second thickness, wherein a third ratio of the first thickness to the second thickness ranges from 5.2 to 7.

In some embodiments, the third ratio ranges from 5.8 to 6.5.

In some embodiments, the thin film transistor further comprises an insulating protective layer covering the source and the drain. The insulating protective layer comprises: a first surface in contact with a first side edge of the source close to the drain; a second surface in contact with a second side edge of the drain close to the source; and a third surface in contact with a surface of the second semiconductor layer away from the gate insulating layer and adjacent to the first surface and the second surface, wherein a comprised angle between the third surface and the first surface is a first comprised angle, an a comprised angle between the third surface and the second surface is a second comprised angle, and at least one of the first comprised angle or the second comprised angle is greater than 90 degrees and less than or equal to 110 degrees.

In some embodiments, a conductivity type of the first semiconductor layer is n type, and the second semiconductor layer is an intrinsic semiconductor layer.

In some embodiments, a material of each of the first semiconductor layer and the second semiconductor layer comprises amorphous silicon.

In some embodiments, the material of the second semiconductor layer comprises hydrogenated amorphous silicon.

In some embodiments, the thickness of the gate insulating layer ranges from 4500 angstroms to 5000 angstroms; and the thickness of the active layer ranges from 1000 angstroms to 1500 angstroms.

In some embodiments, the first ratio ranges from 3.4 to 3.8.

In some embodiments, the gate is located between the base substrate and the gate insulating layer.

According to another aspect of the embodiments of the present disclosure, provided is an array substrate, comprising: a plurality of pixel driving circuits, wherein each of the pixel driving circuits comprises a plurality of thin film transistors, at least one of the plurality of thin film transistors comprising the thin film transistor according to any of the above embodiments.

According to a further aspect of the embodiments of the present disclosure, a display panel is provided. The display panel comprises the array substrate according to any of the above embodiments.

According to still another aspect of the embodiments of the present disclosure, a display device is provided. The display device comprises the display panel according to any of the above embodiments.

According to yet another aspect of the embodiments of the present disclosure, a manufacturing method of a thin film transistor is provided. The manufacturing method comprises: forming a gate, an active layer and a gate insulating layer on one side of a base substrate, wherein the gate insulating layer is located between the gate and the active layer; and forming a source and a drain which are spaced apart from each other and both in contact with the active layer, wherein a first ratio of a thickness of the gate insulating layer to a thickness of the active layer ranges from 3 to 4.

In some embodiments, the active layer comprises: a first semiconductor layer which is heavily doped and comprises a first portion and a second portion spaced apart from each other, wherein the first portion is in contact with the source and the second portion is in contact with the drain; and a second semiconductor layer located between the first semiconductor layer and the gate insulating layer, and in contact with the gate insulating layer.

Other features, aspects and advantages of the present disclosure will become apparent from the following detailed description of exemplary embodiments of the present disclosure with reference to the accompanying drawings.

### BRIEF DESCRIPTION OF THE ACCOMPANYING DRAWINGS

The accompanying drawings, which constitute part of this specification, illustrate exemplary embodiments of the present disclosure and, together with this specification, serve to explain the principles of the present disclosure.

The present disclosure can be more clearly understood from the following detailed description with reference to the accompanying drawings, in which:

FIG. 1 is a schematic structural view showing a thin film transistor according to an embodiment of the present disclosure;

FIG. 2 is a schematic view showing the change of on-state current of a thin film transistor in the function of a first ratio T1/T2;

FIG. 3 is a schematic view showing the change of the on-state current of a thin film transistor in the function of a second ratio T1/T3;

FIG. 4 is a schematic structural view showing a thin film transistor according to another embodiment of the present disclosure;

FIG. 5 is a schematic top view showing a channel according to an embodiment of the present disclosure;

FIG. 6A is an I-V curve of a thin film transistor in a dark state;

FIG. 6B is an I-V curve of a thin film transistor in a photo state;

FIG. 7 is a schematic structural view showing a thin film transistor according to another embodiment of the present disclosure;

FIG. 8 is a flowchart showing a manufacturing method of a thin film transistor according to an embodiment of the present disclosure.

It should be understood that the dimensions of various parts shown in the accompanying drawings are not necessarily drawn according to actual proportional relations. In addition, the same or similar components are denoted by the same or similar reference signs.

### DETAILED DESCRIPTION

Various exemplary embodiments of the present disclosure will now be described in detail with reference to the accompanying drawings. The following description of the exemplary embodiments is merely illustrative and is in no way intended as a limitation to the present disclosure, its application or use. The present disclosure may be implemented in many different forms, which are not limited to the embodiments described herein. These embodiments are provided to make the present disclosure thorough and complete, and fully convey the scope of the present disclosure to those skilled in the art. It should be noticed that: relative arrangement of components and steps, material composition, numerical expressions, and numerical values set forth in these embodiments, unless specifically stated otherwise, should be explained as merely illustrative, and not as a limitation.

The use of the terms “first”, “second” and similar words in the present disclosure do not denote any order, quantity, or importance, but are merely used to distinguish between different parts. A word such as “comprise”, “have” or variants thereof means that the element before the word covers the element(s) listed after the word without excluding the possibility of also covering other elements. The terms “up”, “down”, or the like are used only to represent a relative positional relationship, and the relative positional relationship may be changed correspondingly if the absolute position of the described object changes.

In the present disclosure, when it is described that a specific component is disposed between a first component and a second component, there may be an intervening component between the specific component and the first component or between the specific component and the second component. When it is described that a specific part is connected to other parts, the specific part may be directly connected to the other parts without an intervening part, or not directly connected to the other parts with an intervening part.

Unless otherwise defined, all terms (including technical and scientific terms) used herein have the same meanings as the meanings commonly understood by one of ordinary skill in the art to which the present disclosure belongs. It should also be understood that terms as defined in general dictionaries, unless explicitly defined herein, should be interpreted as having meanings that are consistent with their meanings in the context of the relevant art, and not to be interpreted in an idealized or extremely formalized sense.

Techniques, methods, and apparatus known to those of ordinary skill in the relevant art may not be discussed in detail, but where appropriate, these techniques, methods, and apparatuses should be considered as part of this specification.

With the increased resolution of the display panel, the picture quality of the display panel is also required to be enhanced. However, in the display panel with a high resolution such as 8K resolution, poor display is increasing.

Through analysis, the inventors have noticed that, the performance of the thin film transistor in the array substrate of the display panel affects the display effect of the display panel. Through studies, the inventors provide the following technical solutions to optimize the performance of the thin film transistor. Description will be made below in conjunction with different embodiments.

By analyzing the relationship between the thicknesses of the gate insulating layer and the active layer in the thin film transistor, the inventors have found that, the ratio of the thicknesses of the gate insulating layer and the active layer has an influence on the on-state current of the thin film transistor.

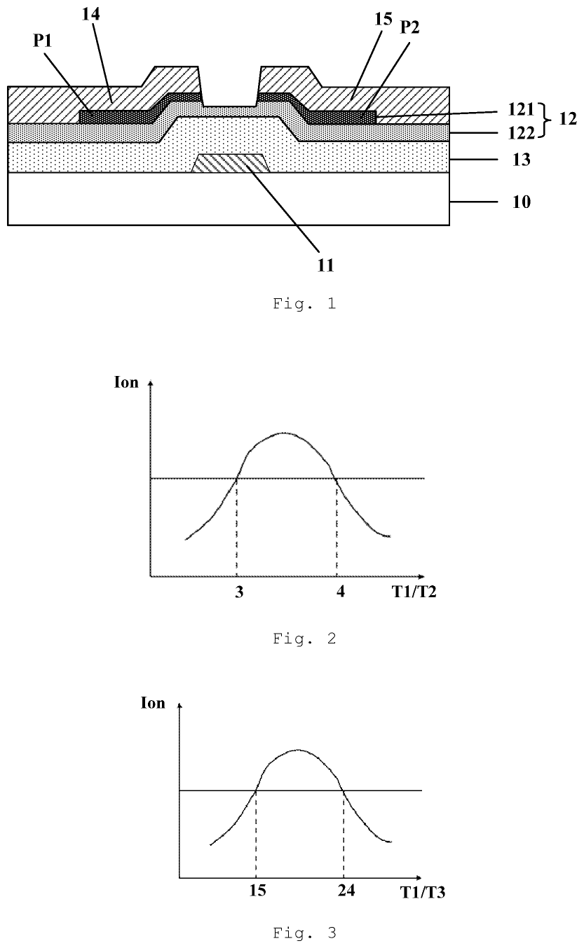

FIG. 1 is a schematic structural view showing a thin film transistor according to an embodiment of the present disclosure.

As shown in FIG. 1, the thin film transistor comprises a gate 11, an active layer 12, a gate insulating layer 13, a source 14 and a drain 15.

The gate 11 and the active layer 12 are both located on one side of the base substrate 10. For example, the base substrate 10 may be a glass substrate or the like. As some implementations, referring to FIG. 1, the active layer 12 may comprise a plurality of semiconductor layers, for example, a first semiconductor layer 121 and a second semiconductor layer 122. As other implementations, the active layer 12 may also comprise only one semiconductor layer.

The gate insulating layer 13 is located between the gate 11 and the active layer 12. In some embodiments, referring to FIG. 1, the gate 11 is located between the base substrate 10 and the gate insulating layer 13.

The source 14 and the drain 15 are spaced apart from each other, and both in contact with the active layer 12. It should be understood that the source 14 and the drain 15 are in contact with different portions of the active layer 12, respectively.

Here, the first ratio T1/T2 of the thickness T1 of the gate insulating layer 13 to the thickness T2 of the active layer 12 ranges from 3 to 4. For example, the first ratio T1/T2 may be 3.2, 3.5, 3.6, 3.8, etc.

It should be understood that the thickness T2 of the active layer 12 refers to the thickness of the active layer 12 as a whole. For example, in a case where the active layer 12 comprises a plurality of semiconductor layers, some parts of the active layer have a smaller thickness, while other parts have a greater thickness. As a whole, the smaller thickness and the greater thickness each is presented as T2, and both satisfy that the T1/T2 ranges from 3 to 4.

In the above embodiments, T1/T2 ranges from 3 to 4, which is helpful to improve the on-state current of the thin film transistor and can ensure the insulation and withstand voltage capability of the gate insulating layer 13.

In some embodiments, the thickness T1 of the gate insulating layer 13 ranges from 4500 angstroms to 5000 angstroms, and the thickness T2 of the active layer 12 ranges from 1000 angstroms to 1500 angstroms. For example, T1 is 4700 angstroms, 4800 angstroms, 4900 angstroms, etc. For example, T2 is 1200 angstroms, 1300 angstroms, 1400 angstroms, etc.

In some embodiments, the first ratio T1/T2 ranges from 3.4 to 3.8, for example, 3.5, 3.6, 3.7, etc. In this way, the on-state current of the thin film transistor and the insulation and withstand voltage capability of the gate insulating layer 13 can be balanced at the same time.

When the gate-source voltage Vgs>the threshold voltage Vth, and the drain-source voltage Vds<Vgs-Vth, the thin film transistor operates in a non-saturation region, and the current of the thin film transistor in the non-saturation region can be expressed by the following formula:

$${I}_{ds} = μ \cdot {C}_{ox} \cdot \frac{W}{L} ( {V}_{gs} - {V}_{th} - \frac{1}{2} {V}_{ds} ) \cdot {V}_{ds}$$

Where μ is the electron mobility, Cₒₓ is the capacitance per unit area of the metal-insulator-semiconductor (MIS) structure in the thin film transistor, and W/L represents the ratio of the channel width to the channel length of the thin film transistor.

Assume that Vgs, Vth and Vds all remain constant, and the relevant parts of the three variables are set as a constant 1, the above formula can be transformed into:

$${I}_{ds} = μ \cdot {C}_{o x} \cdot \frac{W}{L}$$

Where μ is proportional to the thickness T2 of the active layer 12, and Cₒₓ is inversely proportional to the thickness T1 of the gate insulating layer 13. When W/L is a fixed value, the above formula can be transformed into:

I_{ds}=(T2/T1)·μ·Cₒₓ·W/L

Through analysis, the change of T1/T2 will result in the change of the on-state current of the thin film transistor.

FIG. 2 is a schematic view showing the change of the on-state current of a thin film transistor in the function of a first ratio T1/T2.

As shown in FIG. 2, the on-state current Iₒₙ exhibits a tendency of increasing before decreasing with the increase of the first ratio T1/T2. As verified by experiments, in the case where the first ratio T1/T2 is within the range of 3 to 4, the on-state current of the thin film transistor is improved, and the insulation and withstand voltage capability of the gate insulating layer 13 is ensured.

In some embodiments, the active layer 12 of the thin film transistor comprises a plurality of semiconductor layers. Referring to FIG. 1, the active layer 12 comprises a first semiconductor layer 121 and a second semiconductor layer 122, and the first semiconductor layer 121 is a heavily doped semiconductor layer. For example, the conductivity type of the first semiconductor layer 121 is n-type. As some implementations, the second semiconductor layer 122 is an intrinsic semiconductor layer.

The first semiconductor layer 121 comprises a first portion P1 and a second portion P2 spaced apart from each other, the first portion P1 is in contact with the source 14, and the second portion P2 is in contact with the drain 15. In other words, a portion of the first semiconductor layer 121 that is in contact with the source 14 is the first portion P1, and a portion of the first semiconductor layer 121 that is in contact with the drain 15 is the second portion P2.

The second semiconductor layer 122 is located between the first semiconductor layer 121 and the gate insulating layer 13, and in contact with the gate insulating layer 13. In some embodiments, the second semiconductor layer 122 is in contact with the first semiconductor layer 121, that is, there is no additional layer therebetween.

In some embodiments, the materials of the first semiconductor layer 121 and the second semiconductor layer 122 comprise amorphous silicon. For example, the material of the first semiconductor layer 121 comprises n-type heavily doped amorphous silicon (a-Si), and the material of the second semiconductor layer 122 comprises hydrogenated amorphous silicon (a-Si—H).

The inventors have noticed that in the case where the active layer 12 comprises the first semiconductor layer 121 and the second semiconductor layer 122, since the leakage current of the thin film transistor is mainly hole current formed by thermionic emission of the channel, a PN junction will be formed between a hole accumulation layer in the channel and the first semiconductor layer. With this PN junction, the current can only flow out from the hole accumulation layer and cannot flow inwards from the outside of the hole accumulation, which can effectively reduce the output efficiency of the hole. As such, the inventors have realized that the on-state current of the thin film transistor can be further adjusted by adjusting the thickness T3 of the first semiconductor layer 121.

In some embodiments, the second ratio T1/T3 of the thickness T1 of the gate insulating layer 13 to the thickness T3 of the first semiconductor layer 121 ranges from 15 to 24. In this way, the on-state current of the thin film transistor can be further improved. For example, the second ratio T1/T3 is 17, 18, 20, 22, etc.

FIG. 3 is a schematic view showing the change of the on-state current of a thin film transistor in the function of a second ratio T1/T3.

As verified by experiments, when the ratio of the thickness T2 of the active layer to the thickness T3 of the first semiconductor layer is within the range of 5 to 6, the on-state current of the thin film transistor is large.

As shown in FIG. 3, the on-state current Iₒₙ presents a tendency of increasing before decreasing with the increase of the second ratio T1/T3. In a case where the second ratio T1/T3 ranges from 15 to 24, the on-state current of the thin film transistor can be further increased.

In some embodiments, the second ratio T1/T3 ranges from 18 to 22, for example, the second ratio T1/T3 is 19, 20, 21, etc. In this way, the on-state current of the thin film transistor can be further improved.

The inventors have also noticed that the off-state current of the thin film transistor can be adjusted by adjusting the width-length ratio of the channel of the thin film transistor. To further improve the performance of the thin film transistor, the embodiments of the present disclosure also provide the following technical solutions to reduce the off-state current of the thin film transistor.

FIG. 4 is a schematic structural view showing a thin film transistor according to another embodiment of the present disclosure.

As shown in FIG. 4, the first portion P1 of the first semiconductor layer 121 is in contact with the third portion P3 of the second semiconductor layer 122, the second portion P2 of the first semiconductor layer 121 is in contact with the fourth portion P4 of the second semiconductor layer 122, and a portion of the second semiconductor layer 122 between the third portion P3 and the fourth portion P4 is a channel CL. Here, the width-length ratio W/L of the channel CL ranges from 0.52 to 0.6.

In the above embodiments, the width-length ratio W/L of the channel CL ranges from 0.52 to 0.6, which is helpful to reduce the off-state current of the thin film transistor, thereby facilitating to improve the pixel voltage retention rate of a pixel driving circuit comprising the thin film transistor.

In some embodiments, the width-length ratio W/L of the channel CL ranges from 0.54 to 0.58, for example, 0.56, 0.57, etc. In this way, the off-state current of the thin film transistor can be further reduced.

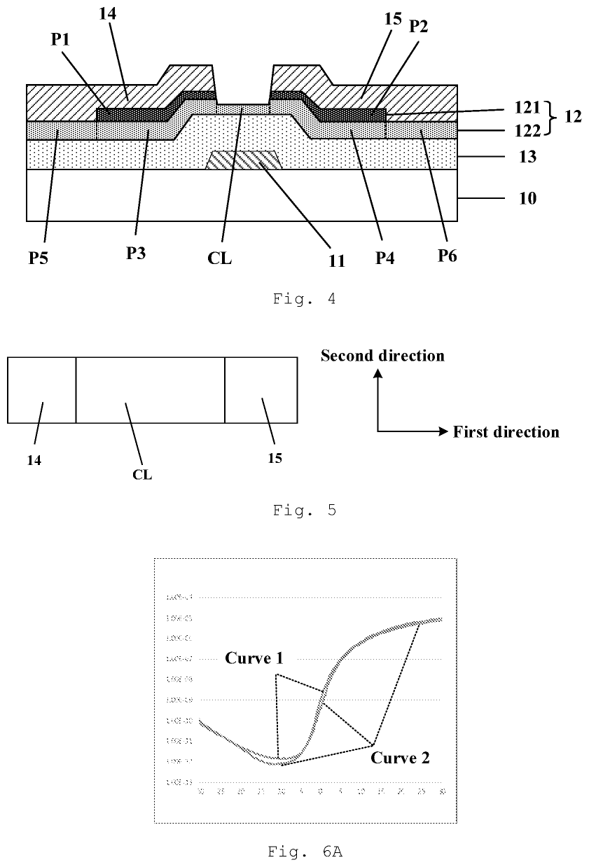

FIG. 5 is a schematic top view showing a channel according to an embodiment of the present disclosure.

As shown in FIG. 5, from the top view of the channel CL, the length of the channel CL can be understood as the length of the channel CL in a first direction from the source 14 to the drain 15, and the width of the channel CL can be understood as the length of the channel CL in a second direction perpendicular to the first direction.

It should be noted that the channel CL, the source 14 and the drain 15 in FIG. 5 are all schematic, but not intended to limit the scope of the present disclosure. It should be understood by those skilled in the art that according to the positions of the gate, the source, and the drain of the thin film transistor, the width and length of the channel can be determined correspondingly, and the width-length ratio of the channel can be determined.

In a case where the first ratio T1/T2 of the thickness T1 of the gate insulating layer 13 and the thickness T2 of the active layer 12 remains constant, the inventors have obtained the changes of the on-state current Ion and the off-state current Ioff of the thin film transistor by studying the changes of the width-length ratio of the channel.

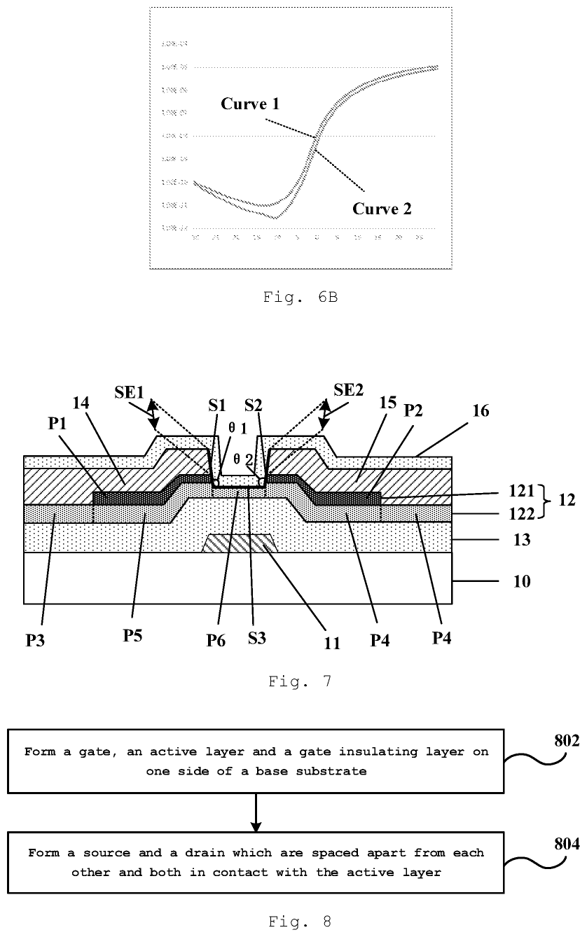

FIG. 6A is an I-V curve of a thin film transistor in a dark state. FIG. 6B is an I-V curve of a thin film transistor in a photo state. It should be understood that the dark state and the photo state here refer to the dark state and photo (bright) state of the display panel in a case where the thin film transistor is applied to the display panel.

In FIGS. 6A and 6B, the width-length ratio W/L of the channel corresponding to the curve 1 is 0.56, and the width-length ratio W/L of the channel corresponding to the curve 2 is 0.72.

Table 1 shows a plurality of parameters of the thin film transistor when the channel has different width-length ratios W/L in the dark state and the photo state.

TABLE 1

| | Dark state | | | | | Photo state | | | | |
|---|---|---|---|---|---|---|---|---|---|---|
| W/L | Ion_15 | Ioff_−8 | Ioff_−20 | Vth1 | Mob | Ion_15 | Ioff_−8 | Ioff_−20 | Vth1 | Mob |
| 0.56 | 1.81 | 1.00 | 5.24 | 2.91 | 0.37 | 2.20 | 5.30 | 10.17 | 1.57 | 0.36 |
| 0.72 | 2.25 | 1.50 | 6.05 | 3.33 | 0.49 | 3.29 | 20.20 | 19.33 | 1.36 | 0.52 |

In Table 1, Ion_15 represents the on-state current of the thin film transistor when the gate-source voltage is 15V, and Ioff_−8 and Ioff_−20 represent the off-state current of the thin film transistor when the gate-source voltage is 8V and 20V respectively. Vth1 represents the threshold voltage of the thin film transistor, and Mob represents the electron mobility of the thin film transistor.

As can be seen from FIG. 6A, FIG. 6B and Table 1, excessively large width-length ratio of the channel leads to a limited improvement of the on-state current Ion but will lead to an apparent increase of the off-state current Ioff. As verified, it is possible to favorably reduce the off-state current Ioff of the thin film transistor in a case where the width-length ratio W/L is within the range of 0.52 to 0.6.

The inventors have also noticed that metal element(s) in the source and drain might diffuse, which leads to the problems such as increased off-state current and short-circuit failure of the thin film transistor, thereby reducing the performance of the thin film transistor, for example, resulting in poor display of the display panel comprising the thin film transistor, such as afterimage, crosstalk, or growing dark spots (GDS).

As found through studies, by adjusting the thickness relationship between the source 14/drain 15 and the second semiconductor layer 122, the diffusion of metal element in the source 14 and the drain 15 can be effectively prevented, thereby further improving the performance of the thin film transistor. Accordingly, the embodiments of the present disclosure also provide the following technical solutions.

Referring to FIG. 4, the source 14 is in contact with a fifth portion P5 of the second semiconductor layer 122, and the drain 15 is in contact with a sixth portion P6 of the second semiconductor layer 122. It should be understood that the source 14 is also in contact with a portion of the second semiconductor layer 122 in addition to the first semiconductor layer 121; and the drain 15 is also in contact with another portion of the second semiconductor layer 122 in addition to the first semiconductor layer 121.

Here, the thickness of each of the source 14 and the drain 15 is a first thickness, the thickness of each of the fifth portion P5 and the sixth portion P6 is a second thickness, and a third ratio of the first thickness to the second thickness ranges from 5.2 to 7. For example, the third ratio is 5.5, 6, 6.5, 6.8, etc. In this way, the diffusion of metal element (for example, copper element) in the source 14 and the drain 15 can be effectively prevented.

In some embodiments, the third ratio ranges from 5.8 to 6.5, and may be, for example, 6.2, 6.3, etc. In this way, the diffusion of metal element in the source 14 and the drain 15 can be more effectively prevented.

FIG. 7 is a schematic structural view showing a thin film transistor according to another embodiment of the present disclosure.

As shown in FIG. 7, the thin film transistor further comprises an insulating protective layer 16 covering the source 14 and the drain 15. For example, the material of the insulating protective layer 16 may comprise nitride of silicon or the like.

The insulating protective layer 16 comprises a first surface S1, a second surface S2 and a third surface S3. It should be understood that each of the first surface S1, the second surface S2 and the third surface S3 is a portion of the bottom surface of the insulating protective layer 16. The insulating protective layer 16 also comprises other surfaces, for example, the top surface and other portions of the bottom surface.

The first surface S1 is in contact with a first side edge SE1 of the source 14 close to the drain 15, and the second surface S2 is in contact with a second side edge SE2 of the drain 15 close to the source 14.

The third surface S3 is in contact with a surface of the second semiconductor layer 122 away from the gate insulating layer 13 (i.e., the top surface of the channel), and adjacent to the first surface S1 and the second surface S2. Here, the comprised angle between the third surface S3 and the first surface S1 is a first comprised angle θ1, and the comprised angle between the third surface S3 and the second surface S2 is a second comprised angle θ2.

The inventors have found that the values of the first comprised angle θ1 and the second comprised angle θ2 have an influence on the diffusion of metal element in the source 14 and the drain 15. To effectively prevent the diffusion of metal element, at least one of the first comprised angle θ1 or the second comprised angle θ2 is greater than 90 degrees and less than or equal to 110 degrees. In some embodiments, at least one of the first comprised angle θ1 or the second comprised angle θ2 may be 95 degrees, 100 degrees, 105 degrees, etc.

In the above embodiments, at least one of the first comprised angle θ1 or the second comprised angle θ2 is greater than 90 degrees and less than or equal to 110 degrees. In this way, diffusion of metal element of at least one of the source 14 or the drain 15 to the gate 11 can be effectively prevented.

It can be understood that the technical solutions of different embodiments above can be combined with each other. In some embodiments, the thin film transistor can be combined with the technical solutions of different embodiments above, thereby further improving the performance of the thin film transistor.

FIG. 8 is a flowchart showing a manufacturing method of a thin film transistor according to an embodiment of the present disclosure.

At step 802, a gate, an active layer, and a gate insulating layer are formed on one side of a base substrate. The gate insulating layer is located between the gate and the active layer.

For example, a gate may be formed on one side of the substrate first, then a gate insulating layer covering the gate is formed, and thereinafter an active layer is formed on one side of the gate insulating layer away from the gate.

For example, the material of the gate insulating layer may comprise oxide of silicon.

At step 804, a source and a drain spaced apart from each other are formed. Here, the source and the drain are both in contact with the active layer.

For example, a metal layer (for example, a copper layer) may be formed first, and then the metal layer is patterned to form a source and a drain which are spaced apart.

Here, the first ratio of the thickness of the gate insulating layer to the thickness of the active layer ranges from 3 to 4.

The thin film transistor formed in the above embodiments is helpful to improve the on-state current of the thin film transistor.

In some embodiments, the structure of the active layer may be the structure described above, which will not be described in detail here.

In some embodiments, the formed thin film transistor may be the thin film transistor according to any of the embodiments described above.

The embodiments of the disclosure also provide an array substrate comprising a plurality of pixel driving circuits. Each pixel driving circuit comprises a plurality of thin film transistors, and at least one of the plurality of thin film transistors comprises the thin film transistor according to any of the above embodiments. It should be understood that the array substrate may further comprise a base substrate, and the plurality of pixel driving circuits is located on one side of the base substrate.

For example, the source 14 of the thin film transistor may be connected to a data line, for example, integrally provided with the data line; and the drain 15 may be connected to a pixel electrode.

Since the on-state current of the thin film transistor increases, it is helpful to improve the driving effect of the pixel driving circuit in the array substrate, thereby facilitating to improving the display effect.

In some embodiments, each thin film transistor in each pixel driving circuit may be the thin film transistor according to any of the above embodiments. In this way, the driving effect of the pixel driving circuit in the array substrate can be further improved, thereby facilitating to further improving the display effect.

The embodiments of the present disclosure also provide a display panel, which comprises the array substrate according to any of the above embodiments. In some embodiments, the display panel may be a liquid crystal display panel. For example, the display panel further comprises a color filter substrate.

The embodiments of the present disclosure also provide a display device, which may comprise the display panel according to any one of the above embodiments. In an embodiment, the display device may be any product or member having a display function, such as a mobile terminal, a television (for example, a television with 8K resolution), a display, a notebook computer, a digital photo frame, a navigator, or an electronic paper.

Hereto, various embodiments of the present disclosure have been described in detail. Some details well known in the art are not described to avoid obscuring the concept of the present disclosure. According to the above description, those skilled in the art would fully know how to implement the technical solutions disclosed herein.

Although some specific embodiments of the present disclosure have been described in detail by way of examples, those skilled in the art should understand that the above examples are only for the purpose of illustration and are not intended to limit the scope of the present disclosure. It should be understood by those skilled in the art that modifications to the above embodiments and equivalently substitution of part of the technical features can be made without departing from the scope and spirit of the present disclosure. The scope of the disclosure is defined by the following claims.

1. A thin film transistor, comprising:
a gate and an active layer which are located on one side of a base substrate;
a gate insulating layer located between the gate and the active layer; and
a source and a drain spaced apart from each other, and both in contact with the active layer,
wherein a first ratio of a thickness of the gate insulating layer to a thickness of the active layer ranges from 3 to 4.

2. The thin film transistor according to claim 1, wherein the active layer comprises:
a first semiconductor layer which is heavily doped and comprises a first portion and a second portion spaced apart from each other, wherein the first portion is in contact with the source and the second portion is in contact with the drain; and
a second semiconductor layer located between the first semiconductor layer and the gate insulating layer, and in contact with the gate insulating layer.

3. The thin film transistor according to claim 2, wherein a second ratio of the thickness of the gate insulating layer to a thickness of the first semiconductor layer ranges from 15 to 24.

4. The thin film transistor according to claim 3, wherein the second ratio ranges from 18 to 22.

5. The thin film transistor according to claim 2, wherein the first portion of the first semiconductor layer is in contact with a third portion of the second semiconductor layer, and the second portion of the first semiconductor layer is in contact with a fourth portion of the second semiconductor layer, wherein a portion of the second semiconductor layer between the third portion and the fourth portion is a channel, a width-length ratio of the channel ranging from 0.52 to 0.6.

6. The thin film transistor according to claim 5, wherein the width-length ratio of the channel ranges from 0.54 to 0.58.

7. The thin film transistor according to claim 2, wherein the source is in contact with a fifth portion of the second semiconductor layer, the drain is in contact with a sixth portion of the second semiconductor layer, a thickness of each of the source and the drain is a first thickness, and a thickness of each of the fifth portion and the sixth portion is a second thickness, wherein a third ratio of the first thickness to the second thickness ranges from 5.2 to 7.

8. The thin film transistor according to claim 7, wherein the third ratio ranges from 5.8 to 6.5.

9. The thin film transistor according to claim 2, further comprising an insulating protective layer covering the source and the drain, the insulating protective layer comprising:
a first surface in contact with a first side edge of the source close to the drain;
a second surface in contact with a second side edge of the drain close to the source; and
a third surface in contact with a surface of the second semiconductor layer away from the gate insulating layer and adjacent to the first surface and the second surface, wherein a comprised angle between the third surface and the first surface is a first comprised angle, an a comprised angle between the third surface and the second surface is a second comprised angle, and at least one of the first comprised angle or the second comprised angle is greater than 90 degrees and less than or equal to 110 degrees.

10. The thin film transistor according to claim 2, wherein a conductivity type of the first semiconductor layer is n type, and the second semiconductor layer is an intrinsic semiconductor layer.

11. The thin film transistor according to claim 2, wherein a material of each of the first semiconductor layer and the second semiconductor layer comprises amorphous silicon.

12. The thin film transistor according to claim 11, wherein the material of the second semiconductor layer comprises hydrogenated amorphous silicon.

13. The thin film transistor according to claim 1, wherein:
the thickness of the gate insulating layer ranges from 4500 angstroms to 5000 angstroms; and
the thickness of the active layer ranges from 1000 angstroms to 1500 angstroms.

14. The thin film transistor according to claim 1, wherein the first ratio ranges from 3.4 to 3.8.

15. The thin film transistor according to claim 1, wherein the gate is located between the base substrate and the gate insulating layer.

16. An array substrate, comprising: a plurality of pixel driving circuits, wherein each of the pixel driving circuits comprises a plurality of thin film transistors, at least one of the plurality of thin film transistors comprising the thin film transistor according to claim 1.

17. A display panel, comprising the array substrate according to claim 16.

18. A display device, comprising the display panel according to claim 17.

19. A manufacturing method of a thin film transistor, comprising:
forming a gate, an active layer and a gate insulating layer on one side of a base substrate, wherein the gate insulating layer is located between the gate and the active layer; and
forming a source and a drain which are spaced apart from each other and both in contact with the active layer,
wherein a first ratio of a thickness of the gate insulating layer to a thickness of the active layer ranges from 3 to 4.

20. The manufacturing method according to claim 19, wherein the active layer comprises:
a first semiconductor layer which is heavily doped and comprises a first portion and a second portion spaced apart from each other, wherein the first portion is in contact with the source and the second portion is in contact with the drain; and
a second semiconductor layer located between the first semiconductor layer and the gate insulating layer, and in contact with the gate insulating layer.
